(19) United States
(12) Patent Application Publication
(10) Pub. No.: US 2021/0296529 A1
(43) Pub. Date: Sep. 23, 2021

(54) Light Emitting Device And Projector

(71) Applicant: Seiko Epson Corporation, Toyko (JP)

(72) Inventors: Hiroaki JIROKU, Suwa (JP); Yoshitomo KUMAI, Okaya (JP)

(21) Appl. No.: 17/202,521

(22) Filed: Mar. 16, 2021

(30) Foreign Application Priority Data
Mar. 17, 2020 (JP) 2020-046485

(51) Int. Cl. H01L 33/20; H01L 33/32; G03B 21/20

(52) U.S. Cl. CPC H01L 33/20; H01L 33/04; G03B 21/2033; H01L 33/32

(57) ABSTRACT

The light emitting device includes a laminated structure having a plurality of columnar parts, wherein the laminated structure includes a first semiconductor layer, a second semiconductor layer different in conductivity type from the first semiconductor layer, a light emitting layer disposed between the first semiconductor layer and the second semiconductor layer, and a third semiconductor layer, the first semiconductor layer and the light emitting layer constitute the columnar part, the second semiconductor layer is disposed between the light emitting layer and the third semiconductor layer, the second semiconductor layer has a plurality of recessed parts, and a surface of the second semiconductor layer which defines the recessed part and a surface of the third semiconductor layer closer to the second semiconductor layer constitute an gap.

The present application is based on, and claims priority from JP Application Serial Number 2020-046485, filed Mar. 17, 2020, the disclosure of which is hereby incorporated by reference herein in its entirety.

### BACKGROUND

### 1. Technical Field

The present disclosure relates to a light emitting device and a projector.

### 2. Related Art

Semiconductor lasers are promising as high-luminance next-generation light sources. In particular, the semiconductor laser having a nano-structure called a nano-column, a nano-wire, a nano-rod, a nano-pillar, or the like is expected to realize a light emitting device capable of obtaining narrow-radiation angle and high-power light emission due to an effect of a photonic crystal.

In JP-A-2007-49062, for example, there is disclosed a light emitting diode obtained by forming an n-type GaN nano-column layer and a light emitting layer on a silicon substrate, then epitaxially growing a p-type GaN contact layer while increasing the nano-column diameter, and then further forming a semi-transparent p-type electrode thereon.

However, in such a light emitting device as described above, it is necessary to consider conditions such as grating matching based on a material of the light emitting layer and a material of a substrate, and the choice of the materials is significantly limited. Therefore, it is difficult to gain the difference in refractive index between the light emitting layer and the cladding layer, and it is difficult to increase the optical confinement factor.

### SUMMARY

A light emitting device according to an aspect of the present disclosure includes a laminated structure having a plurality of columnar parts, wherein the laminated structure includes a first semiconductor layer, a second semiconductor layer different in conductivity type from the first semiconductor layer, a light emitting layer disposed between the first semiconductor layer and the second semiconductor layer, and a third semiconductor layer, the first semiconductor layer and the light emitting layer constitute the columnar part, the second semiconductor layer is disposed between the light emitting layer and the third semiconductor layer, the second semiconductor layer has a plurality of recessed parts, and a surface of the second semiconductor layer which defines the recessed part and a surface of the third semiconductor layer closer to the second semiconductor layer constitute an gap.

A projector according to another aspect of the present disclosure includes the light emitting device according to the above aspect.

### BRIEF DESCRIPTION OF THE DRAWINGS

FIG. 1 is a cross-sectional view schematically showing a light emitting device according to the embodiment.

FIG. 2 is a plan view schematically showing the light emitting device according to the embodiment.

FIG. 3 is a cross-sectional view schematically showing a manufacturing process of the light emitting device according to the embodiment.

FIG. 4 is a cross-sectional view schematically showing the manufacturing process of the light emitting device according to the embodiment.

FIG. 5 is a cross-sectional view schematically showing the manufacturing process of the light emitting device according to the embodiment.

FIG. 6 is a diagram for explaining calculation models.

FIG. 7 is a graph showing a calculation result of the transmittance of 0-order light in each of the calculation models.

FIG. 8 is a graph showing a calculation result of the transmittance of other light than the 0-order light in each of the calculation models.

FIG. 9 is a graph showing a calculation result of the reflectance of the 0-order light in each of the calculation models.

FIG. 10 is a graph showing a calculation result of the reflectance of other light than the 0-order light in each of the calculation models.

FIG. 11 is a diagram schematically showing a projector according to the embodiment.

### DESCRIPTION OF AN EXEMPLARY EMBODIMENT

Some preferred embodiments of the present disclosure will hereinafter be described in detail using the drawings. It should be noted that the embodiments described hereinafter do not unreasonably limit the contents of the present disclosure as set forth in the appended claims. Further, all of the constituents described hereinafter are not necessarily essential elements of the present disclosure.

### 1. LIGHT EMITTING DEVICE

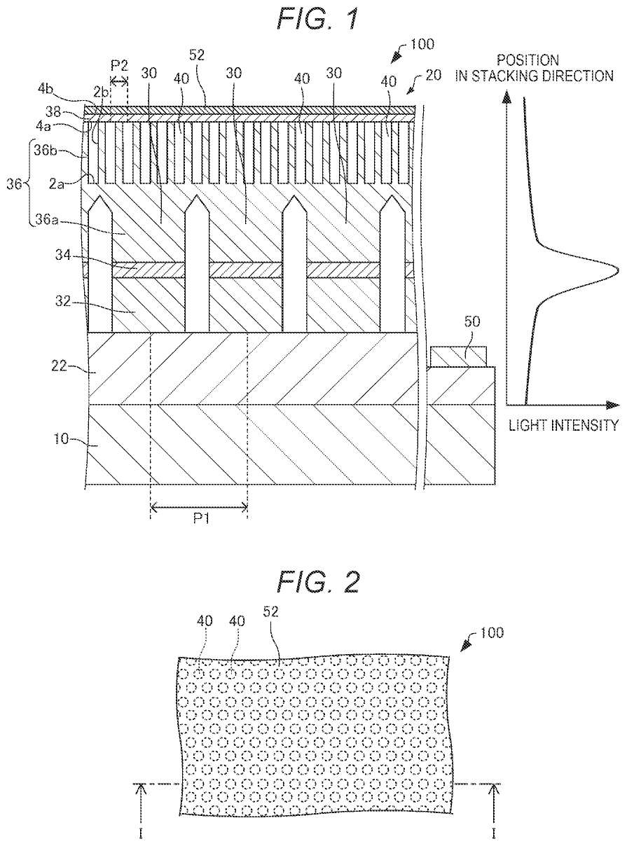

Firstly, a light emitting device according to the present embodiment will be explained with reference to the accompanying drawings. FIG. 1 is a cross-sectional view schematically showing the light emitting device 100 according to the present embodiment. FIG. 2 is a plan view schematically showing the light emitting device 100 according to the present embodiment. It should be noted that FIG. 1 is a cross-sectional view along the line I-I shown in FIG. 2.

The light emitting device 100 has a substrate 10, a laminated structure 20, a first electrode 50, and a second electrode 52.

The substrate 10 is, for example, an Si substrate, a GaN substrate, or a sapphire substrate.

The laminated structure 20 is provided to the substrate 10. The laminated structure 20 has a buffer layer 22, a first semiconductor layer 32, a light emitting layer 34, a second semiconductor layer 36, and a third semiconductor layer 38.

The buffer layer 22 is disposed on the substrate 10. The buffer layer 22 is, for example, an Si-doped n-type GaN layer.

In the present specification, when taking a light emitting layer 34 as a reference in the stacking direction (hereinafter also referred to simply as a “stacking direction”) of the laminated structure 20, the description will be presented assuming a direction from the light emitting layer 34 toward the second semiconductor layer 36 as an “upward direction,” and a direction from the light emitting layer 34 toward a first semiconductor layer 32 as a “downward direction.” Further, the “stacking direction of the laminated structure” denotes a stacking direction of the first semiconductor layer 32 and the light emitting layer 34.

The first semiconductor layer 32 is disposed on the buffer layer 22. The first semiconductor layer 32 is disposed between the substrate 10 and the light emitting layer 34. The first semiconductor layer 32 is an n-type semiconductor layer. The first semiconductor layer 32 is, for example, an Si-doped n-type GaN layer.

The light emitting layer 34 is disposed on the first semiconductor layer 32. The light emitting layer 34 is disposed between the first semiconductor layer 32 and the second semiconductor layers 36. The light emitting layer 34 generates light in response to injection of an electrical current. The light emitting layer 34 has a multiple quantum well structure obtained by stacking quantum well structures each constituted by, for example, an i-type GaN layer doped with no impurity and an i-type InGaN layer.

The second semiconductor layer 36 is disposed on the light emitting layer 34. The second semiconductor layer 36 is disposed between the light emitting layer 34 and the third semiconductor layer 38. The second semiconductor layer 36 is a layer different in conductivity type from the first semiconductor layer 32. The second semiconductor layer 36 is a p-type semiconductor layer. The second semiconductor layer 36 is, for example, an Mg-doped p-type GaN layer. It should be noted that the second semiconductor layer 36 can also be, for example, an Mg-doped p-type AlGaN layer. The first semiconductor layer 32 and the second semiconductor layer 36 are cladding layers having a function of confining the light in the light emitting layer 34.

The first semiconductor layer 32 and the light emitting layer 34 constitute columnar parts 30. In the example shown in FIG. 1, the first semiconductor layer 32, the light emitting layer 34, and a part of the second semiconductor layer 36 constitute the columnar parts 30. The laminated structure 20 has a plurality of the columnar parts 30.

The columnar parts 30 are disposed on the buffer layer 22. The columnar parts 30 each have a columnar shape protruding upward from the buffer layer 22. The columnar part 30 is also referred to as, for example, a nano-column, a nano-wire, a nano-rod, or a nano-pillar. The planar shape of the columnar part 30 is, for example, a polygonal shape or a circle.

The diametrical size of the columnar part 30 is, for example, no smaller than 50 nm and no larger than 500 nm. By making the diametrical size of the columnar part 30 no larger than 500 nm, it is possible to obtain the light emitting layer 34 made of crystals high in quality, and it is possible to reduce the distortion inherent in the light emitting layer 34. Thus, it is possible to amplify the light generated in the light emitting layer 34 with high efficiency. The columnar parts 30 are, for example, equal in diametrical size to each other.

It should be noted that when the planar shape of the columnar part 30 is a circle, the “diametrical size of the columnar part” means the diameter of the circle, and when the planar shape of the columnar part 30 is not a circular shape, the “diametrical size of the columnar part” means the diameter of the minimum encompassing circle. For example, when the planar shape of the columnar part 30 is a polygonal shape, the diametrical size of the columnar part 30 is the diameter of a minimum circle including the polygonal shape inside, and when the planar shape of the columnar part 30 is an ellipse, the diametrical size of the columnar part 30 is the diameter of a minimum circle including the ellipse inside.

The number of the columnar parts 30 disposed is two or more. An interval between the columnar parts 30 adjacent to each other is, for example, no smaller than 1 nm and no larger than 500 nm. The plurality of columnar parts 30 is arranged at a predetermined pitch in a predetermined direction in a plan view viewed from the stacking direction. The plurality of columnar parts 30 is arranged at a first pitch P1 in a first direction in a plan view (hereinafter also referred to simply as “in the plan view”) viewed from the stacking direction. The first direction is a direction in which the columnar parts 30 are arranged at the shortest pitch. The plurality of columnar parts 30 is arranged so as to form, for example, a triangular grid. It should be noted that the arrangement of the plurality of columnar parts 30 is not particularly limited, but the plurality of columnar parts 30 can be arranged to form a square grid. The plurality of columnar parts 30 can develop an effect of a photonic crystal.

It should be noted that the “pitch of the columnar parts” means a distance between the centers of the columnar parts 30 adjacent to each other along the predetermined direction. When the planar shape of the columnar part 30 is a circle, the “center of the columnar part” means the center of the circle, and when the planar shape of the columnar part 30 is not a circular shape, the “center of the columnar part” means the center of the minimum encompassing circle. For example, when the planar shape of the columnar part 30 is a polygonal shape, the center of the columnar part 30 is the center of a minimum circle including the polygonal shape inside, and when the planar shape of the columnar part 30 is an ellipse, the center of the columnar part 30 is the center of a minimum circle including the ellipse inside.

Between the columnar parts 30 adjacent to each other, there is, for example, an gap. It should be noted that it is also possible to dispose a light propagation layer between the columnar parts 30 adjacent to each other. The light propagation layer is, for example, a silicon oxide layer, an aluminum oxide layer, or a titanium oxide layer. It is possible for the light generated in the light emitting layer 34 to pass through the light propagation layers to propagate through the plurality of columnar parts 30 in an in-plane direction perpendicular to the stacking direction.

The second semiconductor layer 36 has columnar portions 36a each forming the columnar part 30, and a layer portion 36b straddling the plurality of columnar parts 30. The columnar portions 36a are each a column-like portion which forms the columnar part 30 in the second semiconductor layer 36. The layer portion 36b is a portion of the second semiconductor layer 36 which constitutes a single layer disposed so as to straddle the plurality of columnar parts 30. The columnar portions 36a have contact with the light emitting layer 34, and the layer portion 36b has contact with the third semiconductor layer 38.

The second semiconductor layer 36 is provided with a plurality of recessed parts 40. The plurality of recessed parts is provided to the layer portion 36b of the second semiconductor layer 36.

The planar shape of the recessed part 40 is a circle as shown in FIG. 2. In other words, a shape of an opening of the recessed part 40 is a circle. It should be noted that the planar shape of the recessed part 40 is not particularly limited, and can also be a polygonal shape, an ellipse, or the like. The planar shape of the recessed part 40 means a shape of the recessed part 40 viewed from the stacking direction.

The diametrical size of the recessed part 40 is, for example, no smaller than 5 nm and no larger than 100 nm. The diametrical size of the recessed part 40 is, for example, smaller than the diametrical size of the columnar part 30. The shape of the recessed part 40 is, for example, a columnar shape.

It should be noted that when the planar shape of the recessed part 40 is a circle, the “diametrical size of the recessed part” means the diameter of the circle, and when the planar shape of the recessed part 40 is not a circular shape, the “diametrical size of the recessed part” means the diameter of the minimum encompassing circle. For example, when the planar shape of the recessed part 40 is a polygonal shape, the diametrical size of the recessed part is the diameter of a minimum circle including the polygonal shape inside, and when the planar shape of the recessed part 40 is an ellipse, the diametrical size of the recessed part is the diameter of a minimum circle including the ellipse inside.

As shown in FIG. 1, the recessed parts 40 are arranged in a second direction at a second pitch P2. The second direction is a direction in which the recessed parts 40 are arranged at the shortest pitch. The second pitch P2 is shorter than the first pitch P1. The second pitch P2 is, for example, about 100 nm. An interval between the recessed parts 40 adjacent to each other is, for example, no smaller than 5 nm and no larger than 500 nm. The plurality of recessed parts 40 is arranged to form, for example, a triangular grid or a quadrangular grid.

As described above, the plurality of columnar parts 30 is arranged in the first direction at the first pitch P1, and the plurality of recessed parts 40 is arranged in the second direction at the second pitch P2. Further, the second pitch P2 is shorter than the first pitch P1. Thus, it is possible to reduce the influence of the plurality of recessed parts 40 exerted on the effect of the photonic crystal developed by the plurality of columnar parts 30. When, for example, the first pitch P1 and the second pitch P2 are equal to each other, the influence of the plurality of recessed parts 40 exerted on the effect of the photonic crystal developed by the plurality of columnar parts 30 becomes significant.

The “pitch of the recessed parts” means a distance between the centers of the recessed parts 40 adjacent to each other along the predetermined direction. When the planar shape of the recessed part 40 is a circle, the “center of the recessed part” means the center of the circle, and when the planar shape of the recessed part 40 is not a circular shape, the “center of the recessed part” means the center of the minimum encompassing circle. For example, when the planar shape of the recessed part 40 is a polygonal shape, the center of the recessed part 40 is the center of a minimum circle including the polygonal shape inside, and when the planar shape of the recessed part 40 is an ellipse, the center of the recessed part 40 is the center of a minimum circle including the ellipse inside.

It should be noted that the recessed parts 40 can randomly be disposed in the second semiconductor layer 36. Thus, it is possible to prevent the recessed parts 40 from developing the effect of the photonic crystal.

The depth of the recessed part 40 is, for example, smaller than the thickness of the layer portion 36b of the second semiconductor layer 36. The depth of the recessed part 40 is the size of the recessed part 40 in the stacking direction. The depth of the recessed part 40 is, for example, no smaller than 100 nm and no larger than 500 nm. The depth of the recessed part 40 can be more than 5 times as large as the diametrical size of the recessed part 40. The inside of the recessed part 40 is an gap.

The third semiconductor layer 38 is disposed on the second semiconductor layer 36. The third semiconductor layer 38 is disposed between the second semiconductor layer 36 and the second electrode 52. The third semiconductor layer 38 is disposed on the second semiconductor layer 36 and the recessed parts 40. The third semiconductor layer 38 closes an opening of each of the recessed parts 40. The third semiconductor layer 38 is a single layer which closes the plurality of recessed parts 40.

The third semiconductor layer 38 is, for example, a layer different in conductivity type from the first semiconductor layer 32. The third semiconductor layer 38 is a p-type semiconductor layer. The third semiconductor layer 38 is, for example, an Mg-doped p-type GaN layer. It should be noted that the third semiconductor layer 38 can also be, for example, an Mg-doped p-type AlGaN layer. The second semiconductor layer 36 and the third semiconductor layer 38 are, for example, the same in composition. The impurity concentration of the second semiconductor layer 36 and the impurity concentration of the third semiconductor layer 38 are, for example, the same. The film thickness of the third electrode 38 is, for example, no smaller than 30 nm and no larger than 100 nm.

Gaps are formed by first surfaces 2a and second surfaces 2b of the second semiconductor layer 36 defining the respective recessed parts 40 and a lower surface 4a of the third semiconductor layer 38 closer to the substrate 10. As shown in FIG. 1, the second semiconductor layer 36 has the first surfaces 2a each defining a bottom of the recessed part 40, and second surfaces 2b each defining a lateral side of the recessed part 40. The third semiconductor layer 38 has the lower surface 4a as a surface closer to the second semiconductor layer 36, and an upper surface 4b as a surface at an opposite side to the second semiconductor layer 36. The lower surface 4a of the third semiconductor layer 38 has contact with the second semiconductor layer 36, and the upper surface 4b of the third semiconductor layer 38 has contact with the second electrode 52. The upper surface 4b of the third semiconductor layer 38 is, for example, flat. The first surface 2a of the second semiconductor layer 36 and the lower surface 4a of the third semiconductor layer 38 are, for example, opposed to each other.

The recessed parts 40 are each surrounded by the first surface 2a and the second surface 2b of the second semiconductor layer 36, and the lower surface 4a of the third semiconductor layer 38. The recessed parts 40 are each defined by the first surface 2a and the second surface 2b of the second semiconductor layer 36, and by closing the opening of the recessed part 40 with the lower surface 4a of the third semiconductor layer 38, the gap is formed.

The first electrode 50 is disposed on the buffer layer 22. It is also possible for the buffer layer 22 to have ohmic contact with the first electrode 50. The first electrode 50 is electrically coupled to the first semiconductor layer 32. In the illustrated example, the first electrode 50 is electrically coupled to the first semiconductor layer 32 via the buffer layer 22. The first electrode 50 is one of the electrodes for injecting the electrical current into the light emitting layer 34. As the first electrode 50, there is used, for example, what is obtained by stacking a Cr layer, an Ni layer, and an Au layer in this order from the buffer layer 22 side.

The second electrode 52 is disposed at the opposite side to the substrate 10 side of the laminated structure 20. The second electrode 52 is provided to the upper surface 4b of the third semiconductor layer 38. The second electrode 52 is electrically coupled to the third semiconductor layer 38. The second electrode 52 is electrically coupled to the second semiconductor layer 36 via the third semiconductor layer 38. The second electrode 52 is the other of the electrodes for injecting the electrical current into the light emitting layer 34. As the second electrode 52, there is used, for example, ITO (indium tin oxide). The film thickness of the second electrode 52 is, for example, no smaller than 100 nm and no larger than 300 nm.

In the light emitting device 100, a pin diode is constituted by the second semiconductor layer 36 of the p-type, the light emitting layer 34, and the first semiconductor layer 32 of the n-type. In the light emitting device 100, when applying a forward bias voltage of the pin diode between the first electrode 50 and the second electrode 52, the electrical current is injected into the light emitting layer 34, and recombination of electrons and holes occurs in the light emitting layer 34. The recombination causes light emission. The light generated in the light emitting layer 34 propagates in a direction perpendicular to the stacking direction due to the first semiconductor layer 32 and the second semiconductor layer 36 to form a standing wave due to the effect of the photonic crystal caused by the plurality of columnar parts 30, and is then gained by the light emitting layer 34 to cause laser oscillation. Then, the light emitting device 100 emits positive first-order diffracted light and negative first-order diffracted light as a laser beam in the stacking direction.

Here, in the light emitting device 100, the second semiconductor layer 36 is provided with the plurality of recessed parts 40, and the recessed part 40 is filled with the gap. Therefore, in the light emitting device 100, it is possible to lower the average refractive index in the in-plane direction of the portion of the second semiconductor layer 36 where the recessed parts 40 are disposed. Thus, it is possible to reduce an amount of leakage of the light generated in the light emitting layer 34 toward the second electrode 52. Therefore, in the light emitting device 100, it is possible to reduce the absorption of the light by the second electrode 52, and thus, it is possible to reduce the loss of the light due to the second electrode 52. As shown in FIG. 1, in the light emitting device 100, for example, it is possible to locate a peak of the light intensity in the light emitting layer 34.

It should be noted that although the light emitting layer 34 of the InGaN type is described above, as the light emitting layer 34, there can be used a variety of types of material system capable of emitting light in response to injection of an electrical current in accordance with the wavelength of the light to be emitted. It is possible to use semiconductor materials of, for example, an AlGaN type, an AlGaAs type, an InGaAs type, an InGaAsP type, an InP type, a GaP type, or an AlGaP type.

### 2. FUNCTIONS AND ADVANTAGES

In the light emitting device 100, the second semiconductor layer 36 has the plurality of recessed parts 40, and the gaps are formed by the first surfaces 2a and second surfaces 2b of the second semiconductor layer 36 which define the respective recessed parts 40, and the lower surface 4a of the third semiconductor layer 38. As described above, in the light emitting device 100, since the second semiconductor layer 36 has the plurality of recessed parts 40, and the recessed parts 40 are each filled with the gap, it is possible to lower the average refractive index in the in-plane direction of the second semiconductor layer 36 as described above. Therefore, in the light emitting device 100, it is possible to improve the optical confinement factor. Therefore, in the light emitting device 100, it is possible to reduce the absorption of the light by the second electrode 52, and thus, it is possible to reduce the loss of the light due to the second electrode 52.

In the light emitting device 100, there is provided the second electrode 52, the third semiconductor layer 38 is disposed between the second semiconductor layer 36 and the second electrode 52. As described above, in the light emitting device 100, since the second electrode 52 is provided to the third semiconductor layer 38 for closing the recessed parts 40, it is possible to prevent the broken line of the second electrode 52, and thus, it is possible to realize the electrode low in resistance.

For example, when disposing the second electrode 52 directly on the second semiconductor layer 36 having the recessed parts 40 without disposing the third semiconductor layer 38, the contact area between the second semiconductor layer 36 and the second electrode 52 is small, and thus, the adhesiveness becomes low, and the broken line occurs in some cases. Further, on the upper surface of the second semiconductor layer 36, there occur defects in some cases due to the etching damage when forming the recessed parts 40. When disposing the second electrode 52 directly on the second semiconductor layer 36, the resistance rises due to the defects.

In the light emitting device 100, since the third semiconductor layer 38 is disposed between the second semiconductor layer 36 and the second electrode 52, such a problem as described above does not arise. Therefore, in the light emitting device 100, it is possible to prevent the broken line of the second electrode 52, and thus, it is possible to realize the electrode low in resistance.

In the light emitting device 100, the first semiconductor layer 32 is an n-type GaN layer, the second semiconductor layer 36 is a p-type GaN layer, and the third semiconductor layer 38 is a p-type GaN layer. As described above, in the light emitting device 100, since the second semiconductor layer 36 and the third semiconductor layer 38 are the same in material as each other, the adhesiveness between the second semiconductor layer 36 and the third semiconductor layer 38 is high. Further, the second semiconductor layer 36 and the third semiconductor layer 38 are the same in material, and are therefore easy to manufacture.

### 3. METHOD OF MANUFACTURING LIGHT EMITTING DEVICE

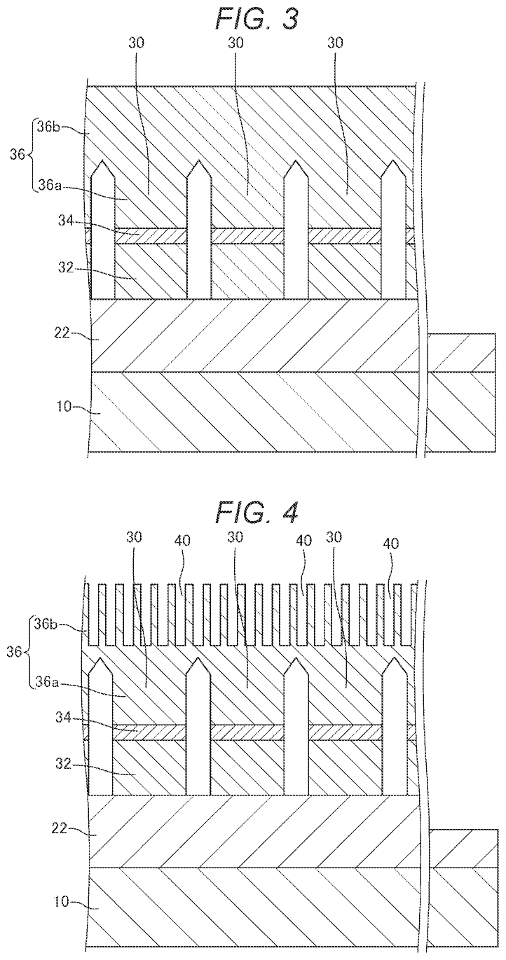

Then, a method of manufacturing the light emitting device 100 according to the present embodiment will be described with reference to the drawings. FIG. 3 through FIG. 5 are cross-sectional views schematically showing a manufacturing process of the light emitting device 100 according to the present embodiment.

As shown in FIG. 3, the buffer layer 22 is grown epitaxially on the substrate 10. As the method of achieving the epitaxial growth, there can be cited, for example, an MOCVD (Metal Organic Chemical Vapor Deposition) method and an MBE (Molecular Beam Epitaxy) method.

Then, a mask layer not shown in FIG. 3 is formed on the buffer layer 22, and then the first semiconductor layer 32, the light emitting layer 34, and the second semiconductor layer 36 are grown epitaxially on the buffer layer 22 using the mask layer as a mask. As the method of achieving the epitaxial growth, there can be cited, for example, the MOCVD method and the MBE method. Thus, the columnar parts 30 are formed.

In the present process, when epitaxially growing the second semiconductor layer 36, the growth is performed in a condition in which the growth occurs not only in the stacking direction but also in the in-plane direction. Thus, the distance between the columnar parts 30 adjacent to each other decreases as the second semiconductor layer 36 grows, and then the columnar parts 30 adjacent to each other are finally connected to each other, and thus, it is possible to form the second semiconductor layer 36 having the columnar portions 36a and the layer portion 36b. The growth condition can be controlled by controlling the growth temperature, a flow rate of a raw material gas, and so on.

As shown in FIG. 4, the plurality of recessed parts is provided to the second semiconductor layer 36. The recessed parts 40 can be formed by using, for example, a photolithography process and an etching process.

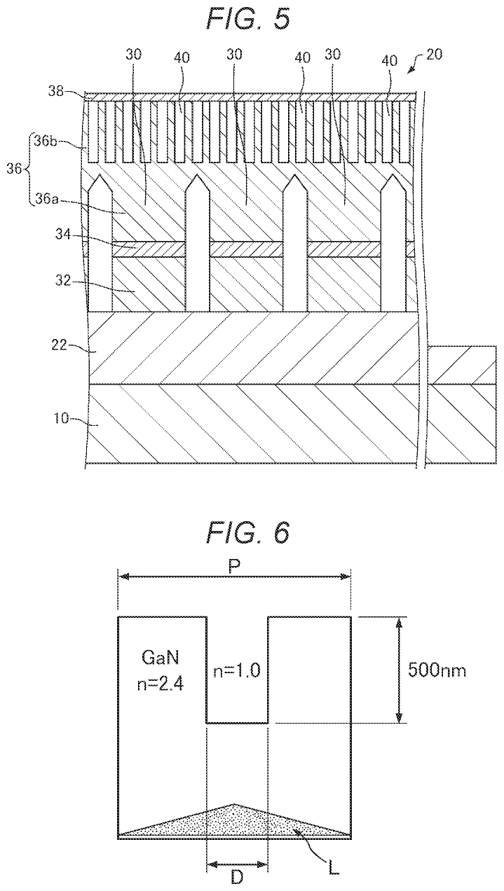

As shown in FIG. 5, the third semiconductor layer 38 is formed on the second semiconductor layer 36. For example, the third semiconductor layer 38 is grown epitaxially on the second semiconductor layer 36. On this occasion, the third semiconductor layer 38 is grown in the condition in which the growth occurs not only in the stacking direction but also in the in-plane direction. As the method of epitaxially growing the third semiconductor layer 38, there can be cited the MOCVD method, the MBE method, and so on.

Then, as shown in FIG. 1, the first electrode 50 is formed on the buffer layer 22, and the second electrode 52 is formed on the third semiconductor layer 38. The first electrode 50 and the second electrode 52 are formed using, for example, a vacuum deposition method. It should be noted that the order of forming the first electrode 50 and the second electrode 52 is not particularly limited.

Due to the process described hereinabove, it is possible to manufacture the light emitting device 100.

### 4. MODIFIED EXAMPLES

### 4.1. First Modified Example

Although in the embodiment described above, there is described when the impurity concentration of the third semiconductor layer 38 and the impurity concentration of the second semiconductor layer 26 are equal to each other, the impurity concentration of the third semiconductor layer 38 can be higher than the impurity concentration of the second semiconductor layer 36. For example, the concentration of Mg in the third semiconductor layer 38 can be higher than the concentration of Mg in the second semiconductor layer 36.

In the light emitting device 100, by making the impurity concentration of the third semiconductor layer 38 higher than the impurity concentration of the second semiconductor layer 36, it is possible to reduce the contact resistance between the third semiconductor layer 38 and the second electrode 52.

### 4.2. Second Modified Example

Although in the embodiment described above, there is described when the first semiconductor layer 32 is the n-type GaN layer, the second semiconductor layer 36 is the p-type GaN layer, and the third semiconductor layer 38 is the p-type GaN layer, the first semiconductor layer 32 can be the n-type GaN layer, the second semiconductor layer 36 can be the p-type GaN layer, and the third semiconductor layer 38 can be a GaN layer including In. In other words, the third semiconductor layer 38 can be an InGaN layer. In this case, the third semiconductor layer 38 can be an i-type semiconductor (intrinsic semiconductor).

Here, by adding In to the GaN layer, a distortion occurs, and an internal electric field is applied. Due to an effect of the internal electric field, it is possible to decrease the electric resistance. Therefore, by using the GaN layer including In as the third semiconductor layer 38, it is possible to reduce the contact resistance between the third semiconductor layer 38 and the second layer 52. Since the contact resistance between the third semiconductor layer 38 and the second electrode 52 can be reduced due to the effect of the internal electric field, it is possible for the third semiconductor layer 38 to be an i-type semiconductor layer with no impurity doped intentionally.

### 4.3. Third Modified Example

Although in the embodiment described above, there is described when the pitch of the recessed parts 40 is an arbitrary length, the pitch of the recessed parts 40, namely a repetition period of the recessed parts 40, can be, for example, shorter than 200 nm. Thus, it is possible to realize the light emitting device low in optical loss and high in light use efficiency. Hereinafter, the reason will be explained showing some calculation examples.

First, there are prepared a calculation model in which the period P of the recessed parts is 100 nm, a calculation model in which the period P of the recessed parts is 200 nm, a calculation model in which the period P of the recessed parts is 400 nm, a calculation model in which the period P of the recessed parts is 1000 nm, and a calculation model in which the period P of the recessed parts is 2000 nm.

FIG. 6 is a diagram for explaining the calculation models. It should be noted that FIG. 6 shows one cycle of the calculation model.

In each of the calculation models, the diametrical size D of the recessed part is assumed to be 30% of the period P. For example, in the calculation model in which the period P of the recessed parts is 100 nm, the diametrical size D of the recessed parts is 30 nm.

Further, in each of the calculation models, it is assumed that the depth of the recessed parts is 500 nm, and the recessed parts are arranged to form the square grid. Further, it is assumed that the light L generated in the light emitting layer is a plane wave, and is TM-polarized light. Further, it is assumed that the refractive index of the second semiconductor layer is n=2.4, the recessed part is filled with the gap, and the refractive index of the inside of the recessed part is n=1.0. With respect to such calculation models, far-field solutions of the transmittance and the reflectance are calculated using the RCWA (Rigorous Coupled Wave Analysis) method.

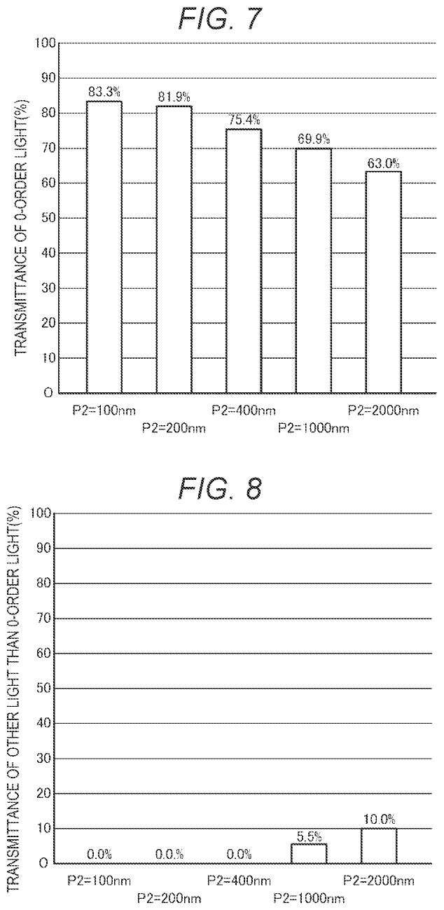

FIG. 7 is a graph representing the calculation result of the transmittance of the 0-order light of each of the calculation models, and FIG. 8 is a graph representing the calculation result of the transmittance of other light than the 0-order light of each of the calculation models. Here, the 0-order light means a rectilinear component of the light L which is generated in the light emitting layer, and then proceeds in the stacking direction.

As shown in FIG. 7, from the calculation result of the transmittance of the 0-order light, it is understood that the transmittance of the 0-order light decreases as the period P of the recessed parts increases. Further, as shown in FIG. 8, from the calculation result of the transmittance of other light than the 0-order light, diffracted light other than the 0-order light can be confirmed with the period P of the recessed parts equal to or longer than 1000 nm. The diffracted light affects a laser radiation angle. Therefore, it is preferable for the period P of the recessed parts to be shorter than 1000 nm.

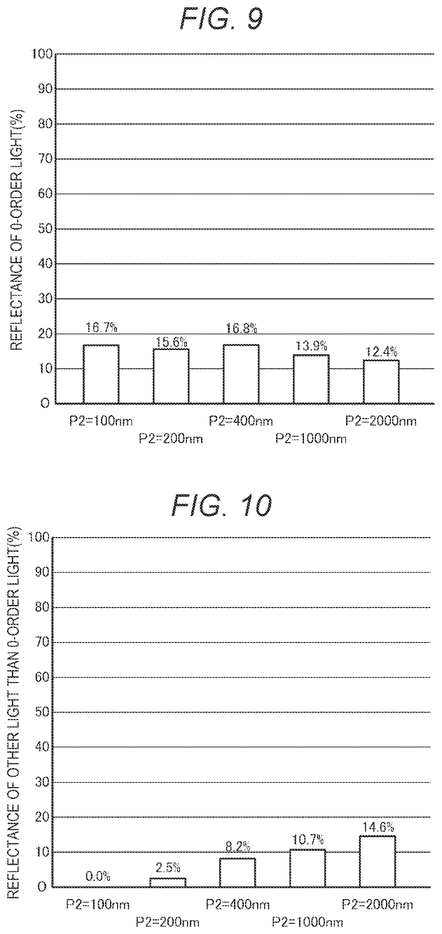

FIG. 9 is a graph representing the calculation result of the reflectance of the 0-order light of each of the calculation models, and FIG. 10 is a graph representing the calculation result of the reflectance of other light than the 0-order light of each of the calculation models.

As shown in FIG. 9, from the calculation result of the reflectance of the 0-order light, it is understood that the influence of the period P of the recessed parts on the reflectance of the 0-order light is small. Further, as shown in FIG. 10, from the calculation result of the reflectance of other light than the 0-order light, diffracted light other than the 0-order light can be confirmed with the period P of the recessed parts equal to or longer than 200 nm. The diffracted light other than the 0-order light becomes the light returning to the light emitting layer, an optical loss, namely a decrease in transmittance, is incurred. Therefore, it is preferable that the period of the recessed parts 40 is shorter than 200 nm, and the diametrical size D of the recessed part 40 is smaller than 60 nm.

By making the period of the recessed parts 40 shorter than 200 nm as described above, it is possible to reduce the diffracted light other than the 0-order light. Therefore, by making the period of the recessed parts 40 shorter than 200 nm, high transmittance can be obtained. In other words, by making the period of the recessed parts 40 shorter than 200 nm, it is possible to realize the light emitting device small in optical loss and high in light use efficiency.

### 5. PROJECTOR

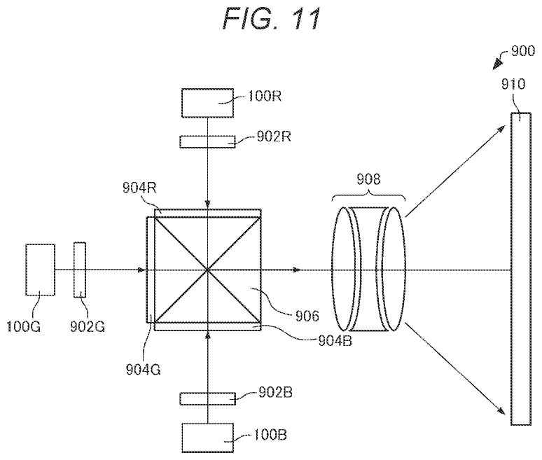

Then, a projector according to the present embodiment will be described with reference to the drawings. FIG. 11 is a diagram schematically showing the projector 900 according to the present embodiment.

The projector 900 has, for example, the light emitting device 100 as a light source.

The projector 900 includes a housing not shown, a red light source 100R, a green light source 100G, and a blue light source 100B which are disposed inside the housing, and respectively emit red light, green light, and blue light. It should be noted that in FIG. 11, the red light source 100R, the green light source 100G, and the blue light source 100B are simplified for the sake of convenience.

The projector 900 further includes a first optical element 902R, a second optical element 902G, a third optical element 902B, a first light modulation device 904R, a second light modulation device 904G, a third light modulation device 904B, and a projection device 908 all installed inside the housing. The first light modulation device 904R, the second light modulation device 904G, and the third light modulation device 904B are each, for example, a transmissive liquid crystal light valve. The projection device 908 is, for example, a projection lens.

The light emitted from the red light source 100R enters the first optical element 902R. The light emitted from the red light source 100R is collected by the first optical element 902R. It should be noted that the first optical element 902R can be provided with other functions than the light collection. The same applies to the second optical element 902G and the third optical element 902B described later.

The light collected by the first optical element 902R enters the first light modulation device 904R. The first light modulation device 904R modulates the incident light in accordance with image information. Then, the projection device 908 projects an image formed by the first light modulation device 904R on a screen 910 in an enlarged manner.

The light emitted from the green light source 100G enters the second optical element 902G. The light emitted from the green light source 100G is collected by the second optical element 902G.

The light collected by the second optical element 902G enters the second light modulation device 904G. The second light modulation device 904G modulates the incident light in accordance with the image information. Then, the projection device 908 projects an image formed by the second light modulation device 904G on the screen 910 in an enlarged manner.

The light emitted from the blue light source 100B enters the third optical element 902B. The light emitted from the blue light source 100B is collected by the third optical element 902B.

The light collected by the third optical element 902B enters the third light modulation device 904B. The third light modulation device 904B modulates the incident light in accordance with the image information. Then, the projection device 908 projects an image formed by the third light modulation device 904B on the screen 910 in an enlarged manner.

Further, it is possible for the projector 900 to include a cross dichroic prism 906 for combining the light emitted from the first light modulation device 904R, the light emitted from the second light modulation device 904G, and the light emitted from the third light modulation device 904B with each other to guide the light thus combined to the projection device 908.

The three colors of light respectively modulated by the first light modulation device 904R, the second light modulation device 904G, and the third light modulation device 904B enter the cross dichroic prism 906. The cross dichroic prism 906 is formed by bonding four rectangular prisms to each other, and is provided with a dielectric multilayer film for reflecting the red light and a dielectric multilayer film for reflecting the blue light disposed on the inside surfaces. The three colors of light are combined with each other by these dielectric multilayer films, and thus, the light representing a color image is formed. Then, the light thus combined is projected on the screen 910 by the projection device 908, and thus, an enlarged image is displayed.

Further, it is possible for the red light source 100R, the green light source 100G, and the blue light source 100B to directly form the images by controlling the light emitting devices 100 as the pixels of the image in accordance with the image information without using the first light modulation device 904R, the second light modulation device 904G, and the third light modulation device 904B. Then, it is also possible for the projection device 908 to project the images formed by the red light source 100R, the green light source 100G, and the blue light source 100B on the screen 910 in an enlarged manner.

Further, although the transmissive liquid crystal light valves are used as the light modulation devices in the example described above, it is also possible to use light valves other than the liquid crystal light valves, or to use reflective light valves. As such light valves, there can be cited, for example, reflective liquid crystal light valves and Digital Micromirror Device™. Further, the configuration of the projection device is appropriately modified in accordance with the type of the light valves used.

Further, by scanning the screen with the light from the light sources 100R, 100G, and 100B, it is possible to apply the light sources 100R, 100G, and 100B also to the light source device of a scanning type image display device having scanning means as an image forming device for displaying an image having a desired size on the display surface.

The light emitting devices according to the embodiment described above can also be used for other devices than projectors. As the applications other than projectors, there can be cited, for example, a light source of indoor and outdoor illumination, a backlight for a display, a laser printer, a scanner, an in-car light, sensing equipment using light, communication equipment, and so on.

It should be noted that the present disclosure is not limited to the embodiments described above, but can be put into practice with a variety of modifications within the scope or the spirit of the present disclosure.

For example, although in the embodiment and the modified examples described above, the first semiconductor layer 32 is disposed between the light emitting layer 34 and the substrate 10 in the laminated structure 20, this is not a limitation, and it is possible to dispose the third semiconductor layer 38 and the second semiconductor layer 36 between the light emitting layer 34 and the substrate 10.

Further, the embodiment and the modified examples described above are illustrative only, and the present disclosure is not at all limited to the embodiment and the modified examples. For example, it is also possible to arbitrarily combine any of the embodiment and the modified examples described above with each other.

The present disclosure includes configurations substantially the same as the configuration described as the embodiment, for example, configurations having the same function, the same way, and the same result, or configurations having the same object and the same advantage. Further, the present disclosure includes configurations obtained by replacing a non-essential part of the configuration described as the embodiment. Further, the present disclosure includes configurations providing the same functions and advantages, and configurations capable of achieving the same object as those of the configuration described as the embodiment. Further, the present disclosure includes configurations obtained by adding known technologies to the configuration described as the embodiment.

The following contents derive from the embodiment and the modified examples described above.

A light emitting device according to an aspect includes a laminated structure having a plurality of columnar parts, wherein the laminated structure includes a first semiconductor layer, a second semiconductor layer different in conductivity type from the first semiconductor layer, a light emitting layer disposed between the first semiconductor layer and the second semiconductor layer, and a third semiconductor layer, the first semiconductor layer and the light emitting layer constitute the columnar part, the second semiconductor layer is disposed between the light emitting layer and the third semiconductor layer, the second semiconductor layer has a plurality of recessed parts, and a surface of the second semiconductor layer which defines the recessed part and a surface of the third semiconductor layer closer to the second semiconductor layer constitute an gap.

In such a light emitting device, since the surface of the second semiconductor layer which defines the recessed part and the surface of the third semiconductor layer closer to the substrate constitute the gap, it is possible to lower the average refractive index in the in-plane direction perpendicular to the stacking direction in the portion of the second semiconductor layer where the recessed parts are disposed. Therefore, in such a light emitting device, it is possible to improve the optical confinement factor.

In the light emitting device according to the aspect, there may further be included an electrode configured to inject an electrical current into the light emitting layer, wherein the third semiconductor layer may be disposed between the second semiconductor layer and the electrode.

In such a light emitting device, since the third semiconductor layer is disposed between the second semiconductor layer and the electrode, it is possible to prevent the broken line of the electrode, and thus, it is possible to realize the electrode low in resistance.

In the light emitting device according to the aspect, an impurity concentration of the third semiconductor layer may be higher than an impurity concentration of the second semiconductor layer.

In such a light emitting device, by making the impurity concentration of the third semiconductor layer higher than the impurity concentration of the second semiconductor layer, it is possible to reduce the contact resistance between the third semiconductor layer and the electrode.

In the light emitting device according to the aspect, the first semiconductor layer may be an n-type GaN layer, the second semiconductor layer may be a p-type GaN layer, and the third semiconductor layer may be a p-type GaN layer.

In such a light emitting device, since the second semiconductor layer and the third semiconductor layer are the same in material as each other, the adhesiveness between the second semiconductor layer and the third semiconductor layer is high. Further, the second semiconductor layer and the third semiconductor layer are the same in material, and are therefore easy to manufacture.

In the light emitting device according to the aspect, the first semiconductor layer may be an n-type GaN layer, the second semiconductor layer may be a p-type GaN layer, and the third semiconductor layer may be a GaN layer including In.

In such a light emitting device, since the third semiconductor layer is the GaN layer including In, it is possible to reduce the contact resistance between the third semiconductor layer and the electrode due to an effect of the internal electric field caused by a distortion.

In the light emitting device according to the aspect, the third semiconductor layer may be an i-type semiconductor layer.

In such a light emitting device, since the third semiconductor layer is the GaN layer including In, it is possible to reduce the contact resistance between the third semiconductor layer and the electrode due to an effect of the internal electric field caused by a distortion. Therefore, even when the third semiconductor layer is the i-type semiconductor layer, it is possible to electrically couple the electrode and the second semiconductor layer to each other.

A projector according to another aspect includes the light emitting device according to one of the above aspects.

What is claimed is:

1. A light emitting device comprising:
a laminated structure having a plurality of columnar parts, wherein
the laminated structure includes
a first semiconductor layer,
a second semiconductor layer different in conductivity type from the first semiconductor layer,
a light emitting layer disposed between the first semiconductor layer and the second semiconductor layer, and
a third semiconductor layer,
the first semiconductor layer and the light emitting layer constitute the columnar part,
the second semiconductor layer is disposed between the light emitting layer and the third semiconductor layer,
the second semiconductor layer has a plurality of recessed parts, and
a surface of the second semiconductor layer which defines the recessed part and a surface of the third semiconductor layer closer to the second semiconductor layer constitute an gap.

2. The light emitting device according to claim 1, further comprising:
an electrode configured to inject an electrical current into the light emitting layer, wherein
the third semiconductor layer is disposed between the second semiconductor layer and the electrode.

3. The light emitting device according to claim 1, wherein
an impurity concentration of the third semiconductor layer is higher than an impurity concentration of the second semiconductor layer.

4. The light emitting device according to claim 1, wherein
the first semiconductor layer is an n-type GaN layer,
the second semiconductor layer is a p-type GaN layer, and
the third semiconductor layer is a p-type GaN layer.

5. The light emitting device according to claim 1, wherein
the first semiconductor layer is an n-type GaN layer,
the second semiconductor layer is a p-type GaN layer, and
the third semiconductor layer is a GaN layer including In.

6. The light emitting device according to claim 5, wherein
the third semiconductor layer is an i-type semiconductor layer.

7. A projector comprising:
the light emitting device according to claim 1.
